(19) United States
(12) Patent Application Publication
(10) Pub. No.: US 2010/0305888 A1
(43) Pub. Date: Dec. 2, 2010

(54) Method and Device for Determining Load Flow in an Electrical Power Supply System

(75) Inventor: Izudin Dzafic, Nurnberg (DE)

Correspondence Address: LERNER GREENBERG STEMER LLP, P O BOX 2480, HOLLYWOOD, FL, 33022-2480, US

(73) Assignee: SIEMENS AKTIENGESELLSCHAFT, Munchen (DE)

(21) Appl. No.: 12/599,148

(22) PCT Filed: May 7, 2007
(86) PCT No.: PCT/DE2007/000828

§ 371 Date: Nov. 6, 2009

(51) Int. Cl. G01R 21/06

(52) U.S. Cl. 702/61

(57) ABSTRACT

A method allows determining load flow in a symmetrical electrical supply grid, particularly a symmetrical electrical distribution grid having asymmetrical loads. The load flow is typically solved within an electrical supply grid by means of an extensive matrix system. The determination of power, voltage, and current at certain node points in the electrical supply grid leads to a large matrix to be solved, which previously had to be solved in whole using algebraic means. By converting the matrix to symmetrical space vector components that can be used to monitor the phase progression of the space vector components, it becomes possible to divide the entire matrix into partial matrices and thus to be able to calculate the partial matrices faster and in parallel using a computer system.

The invention relates to a method for determining load flow in a symmetrical electrical power supply system, in particular a symmetrical electrical distribution network, with asymmetric loads.

For the purpose of investigating load flow, a power supply system is simulated by means of a number of nodes and the lines as connections of the nodes. The sources and sinks are mapped in this case at specific system nodes by generators and loads. The power supply system to be investigated exhibits transverse and longitudinal impedances and capacitances that are to be observed, it being possible at each node of the power supply system to map the system state by the complex voltage U=U*e^{jυ} or by the complex power S=P+j*Q. Two of these four real quantities (U, υ, P, Q) are prescribed, and the two remaining quantities are thereby calculated in the course of the load flow calculation.

The mapping of this equation for all nodes is performed in a system admittance or conductance matrix Y, which can be solved as a whole by various algebraic methods, for example iteration methods for varying the current.

It is problematic in this case that the load flow calculation is traditionally performed for the entire conductance matrix Y, and this is compute-intensive, on the one hand, and prevents parallel processing of the solution iterations, on the other hand.

It is therefore an object of the present invention to provide a load flow calculation that permits fast and parallel processing of the computer operation in order to calculate the load flow in algebraic form.

This object is achieved by the features of patent claim 1. It is provided according to the invention that a complex conductance matrix Y is formed as an assignment between a vector of the independent current sources I_{abc} and a vector of the node voltage V_{abc} as a system of linear equations. The elements of the main diagonal of the conductance matrix Y are denoted as self-admittances, and are components of the sum of all branch admittances relating to the adjacent node, with reference to a common voltage plane. The elements of the secondary diagonal of the conductance matrix Y are denoted as coupling admittances, and form the negative branch admittance relating to adjacent nodes—refered to a common voltage plane. The appropriate matrix element vanishes in the case when no direct connection exists between two nodes.

Subsequently, the conductance matrix Y is converted into three symmetrical component matrices Y0, Y1 and Y2. An asymmetric three-phase system is subdivided by means of the method of the “symmetrical components” into three symmetrical components, the zero phase-sequence system (0 component), the positive phase-sequence system (1 component) and the negative phase-sequence system (2 component). This method has been used to date only for detecting ½-pole short circuits.

The individual symmetrical component matrices Y0, Y1 and Y2 are converted for the purpose of simpler algebraic solution and transformed such that a system of linear equations results that is simple to solve. Subsequently, a voltage vector V₀₁₂ of the symmetrical space vector components is initialized in a fashion split into a (0), (1), and a (2) component with reference to the symmetrical component matrices Y0, Y1 and Y2. This is required since the nonlinear solution can be found only by means of an iterative method. In the context of the so-called flat start condition, by way of example the voltages are assigned specific starting values, no coupling being assumed between the voltage values at the start of the solution.

With the aid of the voltage vector V₀₁₂ of the symmetrical space vector components, the voltage vector V_{abc} is then formed by means of the known conversion matrix A.

The known conversion matrix A has the following form:

$$\begin{matrix}A = [ \begin{matrix}1 & 1 & 1 \\ 1 & {a}^{2} & a \\ 1 & a & {a}^{2}\end{matrix} ] \\ a = {e}^{j120}\end{matrix}$$

and assigns in-phase symmetrical space vector components to the phase-shifted symmetrical space vector components.

Subsequently, the current vector I_{abc} of the symmetrical space vector components is calculated from the complex conjugate power matrix S_{abc} divided by the voltage vector V_{abc} of the symmetrical space vector components (I_{abc}=conj[S_{abc}/V_{abc}]).

The zero phase-sequence, positive phase-sequence and negative phase-sequence system of the current vector I_{abc} is then formed from the inverse matrix A⁻¹ and the current vector I_{abc} of the symmetrical space vector components, and the individual systems of equations VᵢYᵢ=Iᵢ thus formed are solved independently. This method, used to date partially only to check 1- and/or 2-pole short circuits is extended in accordance with the present invention to load flow calculations of power supply systems.

It is regarded as an advantage that Kirchhoff's laws are applied over all feeder nodes into the power supply system and that it is therefore possible to check the plausibility of the solution found.

The conversion of the conductance matrix Y in order to solve the system of equations is solved advantageously by means of a triangular decomposition (LR decomposition) of the symmetrical component matrices Y0, Y1 and Y2 or of the Gaussian elimination method or by means of forming an inverse conductance matrix Y⁻¹.

In an advantageous refinement of the method, it is provided that the calculation of the individual voltage V_{abc} and/or current vectors I_{abc} of the space vector components is carried out in different processors in a computer system.

The matrix multiplications are advantageously optimized for a computer by means of a BLAS (Basic Linear Algebra Subprogram) routine, since BLAS routines are optimized specifically for vector operations.

The power supply system is advantageously an electrical high voltage system. However, it is also possible to make use of the inventive method by applying it to other power supply systems, for example gas supply networks. In order to solve the systems of equations for other gas or water supply networks, it is necessary to use equivalents of the electrical variables.

The terms computer program means are to be understood in the present context as any expression in an arbitrary computer language, code or notation of a set of instructions that enable a computer system for data processing and thus enable the execution of a specific function. The computer program means, the computer program and the computer application can be run either directly or after conversion into another language, code, notation or by representation in another material form on the computer system.

Further advantageous refinements are to be found in the subclaims.

In the case of a symmetrical network configuration—all lines are symmetrical and all transformers are three-phase transformers—there are three independent systems of equations each having seven matrix elements other than zero. The computing time for the systems of equations is reduced by a factor of nine because of the possibility of parallel processing.

1-8. (canceled)

9. A method for determining load flow in a power supply system, which comprises the following steps:
forming a complex conductance matrix Y as an assignment between a vector of the independent current sources I_{abc} and a vector of the node voltage V_{abc} as a system of linear equations;
converting the complex conductance matrix Y into three symmetrical component matrices Y0, Y1, and Y2;
converting the symmetrical component matrices Y0, Y1, and Y2 in order to solve the symmetrical component matrices Y0, Y1, and Y2;
initializing a voltage vector V₀₁₂ of the symmetrical space vector components, split into a (0), (1), and a (2) component with reference to the symmetrical component matrices Y0, Y1, and Y2;
calculating a voltage vector V_{abc} of the symmetrical space vector components by way of the conversion matrix A and transforming by way of the space vector V₀₁₂;
calculating a current vector I_{abc} of the symmetrical space vector components from a complex conjugate conductance matrix S_{abc} divided by the voltage vector V_{abc} of the symmetrical space vector components;
calculating the (0), (1) and (1) and (2) components of the voltage vector I_{abc} of the inverse matrix A⁻¹ and the current vector I_{abc} of the symmetrical space vector components; and
solving the system of equations VᵢYᵢ=Iᵢ by forward elimination and backward substitution, to thereby determine the load flow in the power supply system.

10. The method according to claim 9, which comprises applying Kirchhoff's law to all feeder nodes.

11. The method according to claim 9, which comprises solving the conversion of the conductance matrix Y in order to solve the system of equations by way of a triangular decomposition (LR decomposition) or by way of the Gaussian elimination method or by forming an inverse conductance matrix Y⁻¹.

12. The method according to claim 9, which comprises carrying out the calculation of the individual voltage V_{abc} and/or current vectors I_{abc} of the space vector components in mutually different processors in a computer system.

13. The method according to claim 9, which comprises carrying out the matrix multiplications in optimized fashion for a computer by way of a basic linear algebra subprogram-routine.

14. The method according to claim 9, wherein the power supply system is an electrical high voltage system.

15. A device for carrying out the method according to claim 9.

16. A device for determining load flow in a power supply system, comprising:
inputs for inputting load flow related signals and a plurality of processors programmed to:
form a complex conductance matrix Y as an assignment between a vector of the independent current sources I_{abc} and a vector of the node voltage V_{abc} as a system of linear equations;
convert the complex conductance matrix Y into three symmetrical component matrices Y0, Y1, and Y2;
convert the symmetrical component matrices Y0, Y1, and Y2 in order to solve the symmetrical component matrices Y0, Y1, and Y2;
initialize a voltage vector V₀₁₂ of the symmetrical space vector components, split into a (0), (1), and a (2) component with reference to the symmetrical component matrices Y0, Y1, and Y2;
calculate a voltage vector V_{abc} of the symmetrical space vector components by way of the conversion matrix A and transforming by way of the space vector V₀₁₂;
calculate a current vector I_{abc} of the symmetrical space vector components from a complex conjugate conductance matrix S_{abc} divided by the voltage vector V_{abc} of the symmetrical space vector components;
calculate the (0), (1) and (1) and (2) components of the voltage vector I_{abc} of the inverse matrix A⁻¹ and the current vector I_{abc} of the symmetrical space vector components; and
solve the system of equations VᵢYᵢ=Iᵢ by forward elimination and backward substitution; and
one or more outputs for outputting the results of the solved system of equations to represent the load flow in the power supply system.

17. A computer program product stored in a computer-readable medium and comprising computer-readable means configured to prompt a computer to carry out the method according to claim 9 when the program is running on the computer.
